(19) United States
(12) Patent Application Publication
(10) Pub. No.: US 2019/0062631 A1
(43) Pub. Date: Feb. 28, 2019

(54) PHOSPHOR AND LIGHT EMITTING DEVICE

(71) Applicant: Denka Company Limited, Tokyo (JP)

(72) Inventors: Keita KOBAYASHI, Fukuoka (JP); Hideyuki EMOTO, Fukuoka (JP)

(73) Assignee: Denka Company Limited, Tokyo (JP)

(21) Appl. No.: 16/070,222

(22) PCT Filed: Jan. 13, 2017
(86) PCT No.: PCT/JP2017/001072

§ 371 Date: Jul. 13, 2018

(30) Foreign Application Priority Data
Jan. 15, 2016 (JP) 2016-006587

(51) Int. Cl. C09K 11/70; H01L 33/50

(52) U.S. Cl. CPC C09K 11/706; H01L 33/502; H01L 33/504

(57) ABSTRACT

Provided are a phosphor having long-term reliability and high luminance, and a white light emitting device using the phosphor. In a β-type SiAlON phosphor (a), the volume median particle size D50 [μm] and the average particle size R [μm] calculated from a surface area measured by an air permeability method satisfy the following formula (1):

D50/R<1.4 Formula (1)

### TECHNICAL FIELD

The present invention relates to an LED (Light Emitting Diode) and a light emitting device using a phosphor.

### BACKGROUND ART

The SiAlON-type phosphor known as sialon is a solid solution of a silicon nitride, and a material recently having attracted attention in the field of LED. Among others, a β-type sialon is known as a material represented by a general formula: Si_{6-z}Al_{z}O_{z}N_{8-z}.

As a phosphor used in a white light emitting device, there may be mentioned a combination of a β-type sialon and a red light-emitting phosphor (see Patent Literature 1), and a phosphor as a combination of a red light-emitting phosphor having a specific chromaticity coordinate (color coordinate) and a green light-emitting phosphor having a specific color coordinate (see Patent Literature 2). There may be also mentioned a phosphor controlled with respect to the ratio between the FSSS value measured from the gas flow resistance and the median diameter (D50) in the particle size distribution, for the purpose of improving the dispersibility in the sealing resin of LED (see Patent Literature 3).

### CITATION LIST

### Patent Literature

Patent Literature 1: Japanese Patent Laid-Open No. 2007-180483

Patent Literature 2: Japanese Patent Laid-Open. No. 2008-166825

Patent Literature 3: Japanese Patent Laid-Open No. 2014-095055

### SUMMARY OF INVENTION

### Technical Problem

When an LED according to the above-described conventional technology is prepared, and subjected to a reliability (durability) test in a state of being energized and lit at a high temperature and a high humidity, the reliability is actually insufficient. In particular, in the application of white LED, there have been demanded techniques for improving the resistance to a high-temperature high-humidity environment and the energization reliability.

### Solution to Problem

The present invention provides techniques for improving, in the application of white LED, the resistance to a high-temperature high-humidity environment and energization reliability, by controlling the primary particle size and the secondary particle size of an oxynitride phosphor.

An embodiment of the present invention provides an oxynitride phosphor (a), which is a β-type sialon, having a light-emitting element and a phosphor wavelength-converting the light of the light emitting element, and allowing the volume median particle size D50 [μm] and the average particle size R [μm] calculated from the surface area measured with an air permeability method to satisfy the formula (1):

D50/R<1.4 Formula(1)

In addition, in the phosphor provided in the preferred embodiment of the present invention, when the volume of the whole of the particles is defined as 100%, the particle size D10 [μm] at which the volume integrated from the smallest particle size is 10% in terms of the integrated volume percentage and the particle size D90 [μm] which the volume integrated from the smallest particle size is 90% in terms of the integrated volume percentage satisfy the following formula (2):

1.6>(D90−D10)/D50 Formula (2)

### Advantageous Effects of Invention

By using the phosphor of the present invention, it is possible to provide a white light emitting device having high luminance and a long-term reliability.

### DESCRIPTION OF EMBODIMENT

Hereinafter, the embodiment of the present invention is described in more detail.

The oxynitride phosphor according to the embodiment of the present invention is a β-type sialon, in which Eu²⁺ is solid-dissolved as a light emitting center in a host crystal represented by the general formula: Si_{6-z}Al_{z}O_{z}N_{8-z}. The β-type sialon according to the embodiment of the present invention is also represented by a general formula: Si_{6-z}Al_{z}O_{z}N_{8-z}:Eu (wherein 0<z≤4.2).

In the embodiment of the present invention, the above-described volume median particle size D50, and the above-described particle sizes D10 and D90 related to the phosphor material can be measured by, for example, a laser diffraction type particle size distribution measurement. Here, in the laser diffraction type particle size distribution measurement, when the crystallites are small and aggregated, sizes of the aggregated secondary particles are measured. On the other hand, when the crystallites are not aggregated, the sizes of the crystallites are measured. Therefore, the discrimination between the secondary particle in an aggregated state and the non-aggregated single crystals cannot be performed from the measurement results.

In addition, in the embodiment of the present invention, the average particle size (average particle diameter) R [μm] can be calculated from the specific surface area measured by the air permeability method (such as Blaine method or Fisher method) according to the following formula (3):

R=6/(V×G) Formula (3)

Here, is the specific surface area [m²/g] of the material as the measurement object determined by the air permeability method, and G represents the density [g/cm³] of the material as the measurement object.

The fact that the average particle size R is small means that the specific surface area is large. Even when the measurement object has the same D50, but has a small average particle size R, it is conceivable that the particles takes a form of aggregated small crystallites (a state of having a large number of asperities on the surface).

The present inventors have discovered that when the oxynitride phosphor (a) according to an embodiment of the present invention is small in the value of D50/R (namely, the average particle size R is large in relation to D50), the long-term reliability of the light emitting device is improved, and the luminance is improved. The present invention has been conceived on the basis of this finding. The fact that the value of D50/R is small (the average particle size R is large) means that the crystallite size in relation to D50 is generally large, and the specific surface area is small. In a preferred embodiment, the value of D50/R can be set within a range of 0.5 or more and less than 1.4, more preferably within a range of 0.8 or more and less than 1.4, and further preferably within a range of 1.1 or more and less than 1.4.

The value of (D90−D10)/D50 represents the width of the particle size distribution. When the value of (D90-D10)/D50 is small, the particle size distribution is sharp. In addition, when the samples having the same D50 value are compared with each other, the sample smaller in (D90−D10)/D50 is smaller in the proportion of fine powder. In a phosphor material having a smaller proportion of fine powder, the specific surface area is also decreased, and accordingly, it is conceivable that improved is the reliability when such a phosphor material is used in a light emitting device. In the preferred embodiment, the value of (D90−D10)/D50 may be set within the range of 0.1 or more and less than 1.6, and more preferably within the range of 0.5 or more and less than 1.6.

The phosphor according to an embodiment of the present invention may be used as incorporated into a light emitting device, the crystallites in the phosphor are large in size and have a small specific surface area, and the improvement effect of the reliability as a light emitting device is obtained. The reliability test is performed in an energized state in a high-temperature high-humidity environment, and in general, in the contact position between the phosphor and the resin, the phosphor is susceptible to external influences (such as oxidation, hydrolysis, and precipitation of ions). The present phosphor has a small specific surface area, accordingly the contact positions (areas) between the phosphor and the resin are small in number, and such influences as described above on the phosphor can be reduced. In addition, it is also conceivable that the decrease of the ions generated from the phosphor reduces the influences on the other members such as resins and LED chips, and the reliability is improved.

Moreover, according to the present invention, the larger crystallites and the smaller specific surface areas reduce the reflection from the phosphor. Consequently, the distance of light passing through the resin (optical path length) including phosphors as dispersed therein is short, and hence the attenuation of light (such as nonradiative relaxation) due to the resin and the phosphors is small, and consequently luminance is improved. In addition, the reduction of the light attenuation (such as nonradiative relaxation) decreases the calorific value of the whole LED, and accordingly the reliability as a light emitting device is also improved. Moreover, the smaller specific surface area reduces the reflection due to the phosphor, the frequency of hitting the reflector of the LED package with the light is decreased, thus the loss of light due to the reflection on the reflector is decreased, and consequently the luminance is improved.

The light emitting device according to an embodiment of the present invention has the above-described phosphor, and the LED having the phosphor as mounted on the light emitting surface thereof. The phosphor mounted on the light emitting surface of the LED is sealed with a sealing member. As the sealing member, a resin and a glass may be mentioned, and examples of the resin include, without being limited to, a silicone resin and an epoxy resin. As the LED, a red light emitting LED, a blue light emitting LED, and another color light emitting LED can be appropriately selected, according to the color of the finally emitted light. The peak wavelength of the LED may preferably be 360 nm or more and 460 nm or less, more preferably 440 nm or more and 460 nm or less, and further preferably 445 nm or more and 455 nm or less, in relation to the phosphor.

The size of the light emitting surface of the LED may preferably be 0.5 mm square or more, the size of the LED chip having such a light emitting surface area may be appropriately selected, may preferably be 1.0 mm×0.5 mm, and further preferably 1.2 mm×0.6 mm.

The phosphor according to an embodiment of the present invention may preferably be used as a green phosphor in a white light emitting device. When the green phosphor is used in a light emitting device, the green phosphor may be combined with other phosphors; for example, it is preferable to combine the green phosphor with a red phosphor made of a fluoride or a nitride. It is possible to use, in combination with the phosphor according to the embodiment of the present invention, preferably one or more selected from K₂SiF₆:Mn as the red phosphor made of a fluoride, and CaAlSiN₃:Eu, (Sr,Ca)AlSiN₃:Eu, and Sr₂Si₅:N₈:Eu as the red phosphors made of nitrides.

### EXAMPLES

Examples and Comparative Examples according to the present invention were prepared as follows.

<Method for Producing β-Type Sialon>

As the method for producing a β-type sialon, as described below, there were performed a firing step of firing the starting materials after the starting materials were mixed, a heat treating step performed after the fired product was pulverized, and an acid treatment step of removing impurities from the powder, after the heat treatment step.

<Firing Step>

In Example 1, an α-type silicon nitride powder (SN-E10 grade, manufactured by Ube Industries, Ltd.), an aluminum nitride powder (E grade, manufactured by Tokuyama Corp.), an aluminum oxide powder (TM-DAR grade, manufactured by Taimei Chemicals Co., Ltd.), and europium oxide (RU grade, manufactured by Shin-Etsu Chemical Co., Ltd.) were mixed so as for the formulation to satisfy Si:Al:O:Eu=5.95:0.05:0.05:0.02, and thus a raw material mixture was obtained.

The raw material mixture was subjected to a mixing with a dry ball mill by using a nylon pot and balls made of silicon nitride. Subsequently, the mixture was allowed to pass through a sieve having an opening of 150 μm to remove aggregates, and thus a raw material powder was obtained.

The raw material powder was filled in a cylindrical boron nitride container equipped with a lid (manufactured by Denka Co., Ltd.), the raw material powder was fired in an electric furnace having a carbon heater, in a pressurized nitrogen atmosphere at 0.8 MPa, at 2000° C. for 10 hours, and thus a β-type sialon product was obtained. The product was pulverized with a ball mill (alumina balls), then the pulverized product was sieved with a sieve having an opening of 45 μm, and thus a produced powder of β-type sialon was obtained.

<Heat Treatment Step>

The produced powder was filled in a cylindrical boron nitride container, the produced powder was heat treated in an electric furnace having a carbon heater, in an atmosphere of argon flow at atmospheric pressure, at 1500° C. for 7 hours, and thus a β-type sialon heat treated powder was obtained.

<Acid Treatment Step>

The β-type sialon heat treated powder was immersed in a mixed acid of hydrofluoric acid and nitric acid. Subsequently, the decantation to remove the supernatant liquid and the fine powder was repeated until the solution became neutral, the finally obtained precipitate was filtered, dried, and sieved through a sieve having an opening of 45 μm, and thus the β-type sialon of Example 1 was obtained.

The green phosphor of Example 2 was prepared by mixing the raw materials so as for the formulation to satisfy Si:Al:O:Eu=5.85:0.15:0.15:0.02, and by processing in the same manner as in Example 1 in the ether steps.

The green phosphor of Example 3 was prepared by mixing the raw materials so as for the formulation to satisfy Si:Al:O:Eu=5.80:0.20:0.20:0.02, and by processing in the same manner as in Example 1 in the other steps.

The green phosphor of Example 4 was prepared by mixing the raw materials so as for the formulation to satisfy Si:Al:O:Eu=5.80:0.20:0.20:0.02, performing a firing at 2000° C. for 20 hours, omitting the ball mill pulverization, and excessively performing removal of fine powder based on decantation, and by processing in the same manner as in Example 1 in the other steps.

The green phosphor of Example 5 was prepared by mixing the raw materials so as for the formulation to satisfy Si:Al:O:Eu=5.80:0.20:0.20:0.02, by regulating the particle size by altering the conditions of the ball mill pulverization after firing and the decantation, and regulating so as for the coarse powder and the fine powder to remain in large amounts, and by processing in the same manner as in Example 1 in the other steps.

The green phosphor of Comparative Example 1 was prepared by mixing the raw materials so as for the formulation to satisfy Si:Al:O:Eu=5.95:0.05:0.05:0.02, performing firing at 1950° C., regulating the conditions of the pulverization after firing, and regulating the removal of the fine powder based on decantation, and by processing in the same manner as in Example 1 in the other steps.

The green phosphor of Comparative Example 2 was prepared by mixing the raw materials so as for the formulation to satisfy Si:Al:O:Eu=5.8:0.15:0.15:0.02, and by processing in the same manner as in Comparative Example 1 in the other steps.

The green phosphor of Comparative Example 3 was prepared by mixing the raw materials so as for the formulation to satisfy Si:Al:O:Eu=5.80:0.20:0.20:0.02, and by processing in the same manner as in Comparative Example 1 in the other steps.

The green phosphor of Comparative Example 4 was prepared by mixing the raw materials so as for the formulation to satisfy Si:Al:O:Eu=5.80:0.20:0.20:0.02, regulating the particle size by altering the conditions of the pulverization after firing and the decantation, and regulating so as for the coarse powder and the fine powder to remain in large amounts, and by processing in the same manner as in Comparative Example 1 in. the other steps.

The green phosphor of Comparative Example 5 was prepared by mixing the raw materials so as for the formulation to satisfy Si:Al:O:Eu=5.95:0.05:0.05:0.02, regulating the particle size by altering the conditions of the pulverization after firing and the decantation, and regulating so as for the coarse powder and the fine powder to remain in large amounts, and by processing in the same manner as in Comparative Example 1 in the other steps.

The green phosphor of Comparative Example 6 was prepared by mixing the raw materials so as for the formulation to satisfy Si:Al:O:Eu=5.85:0.15:0.15:0.02, regulating the particle size by altering the conditions of the pulverization after firing and the decantation, and regulating so as for the coarse powder and the fine powder to remain in large amounts, and by processing in the same manner as in Comparative Example 1 in the other steps.

The above-described powder properties and physical properties of the green phosphors according to Examples 1 to 5 and Comparative Examples 1 to 6 were measured as follows, and the results thus obtained are shown in Tables 1 to 3 presented below.

<Fluorescence Intensity>

The fluorescence intensity (emission intensity) of the phosphor was presented in terms of the relative percentage based on the peak height of a standard sample (YAG phosphor P46Y3, manufactured by Mitsubishi Chemical Corp.) taken as 100%. As the fluorescence intensity measurement apparatus, the model F-7000 fluorescence spectrophotometer manufactured by Hitachi High-Technologies Corp. was used. The measurement method is as follows.

<Measurement Method of Fluorescence Intensity>

1) Sample Set: A measurement sample and a standard sample were each filled in a quartz cell, and the measurement was performed by alternately setting the quartz cells in the measurement apparatus sufficiently subjected to aging. The samples were filled in the cell so as to reach approximately ¾ the cell height so as for the relative packing density to be approximately 35%.

2) Measurement: The sample was excited with a light of 455 nm, and the height of the maximum peak in 500 to 700 nm was read. The measurement was repeated five times, the maximum value and the minimum value were eliminated, and the average value of the rest three values was taken as the measurement value.

<Chromaticity x>

The chromaticity x is the value of CIE1931, and was measured with a spectrophotometer (MCPD-7000, manufactured by Otsuka Electronics Co., Ltd.).

<Peak Wavelength>

The peak wavelength was measured with a spectrophotometer (MCPD-7000, manufactured by Otsuka Electronics Co., Ltd.).

<Measurement of Particle Sizes>

The particle sizes (D10, D50, D90) were measured with the Microtrac MT3300EXII (MicrotracBEL Corp.). In 100 cc of ion-exchanged water, 0.5 g of a sample was placed, the resulting mixture was subjected to a dispersion treatment with the Ultrasonic Homogenizer US-150E (Nihonseiki Kaisha Ltd., chip size: φ20, Amplitude: 100%, oscillation frequency: 19.5 kHz, amplitude: approximately 31 μm) for 3 minutes, and then subjected to a particle size measurement with MT33.00EXII.

<Measurement Method of Specific Surface Area by Air Permeability Method>

The measurement of the specific surface area by the air permeability method was performed according to JIS R5201 (Blaine specific surface area test). The particle density G was set to be 3.25 [g/cm³].

<Calculation Method of Average Particle Size (Average Particle Diameter)>

The average particle size (average particle diameter) R [μm] can be calculated from the specific surface area measured with the air permeability method according to the following formula (3):

R=6/(V×G) Formula (3)

Here, V is the specific surface area [m²/g] determined by applying the air permeability method to the material as the measurement object, and G represents the density [g/cm³]. G was measured with MAT-7000 (Seishin Enterprise Co., Ltd.).

TABLE 1

| | | Powder properties and physical properties of green phosphor | | | | | | |
|---|---|---|---|---|---|---|---|---|
| | | Excitation at 455 nm | | | | | | |
| | | Emission | | Peak | Particle size | | | |
| | | intensity | Chromaticity | wavelength | D10 | D50 | D90 | |
| | | (%) | x | (nm) | (μm) | (μm) | (μm) | (D90 − D10)/D50 |
| Phosphor | Example 1 | 185 | 0.285 | 529 | 6.0 | 12.9 | 25.0 | 1.5 |
| (a) | | | | | | | | |
| — | Comparative | 187 | 0.286 | 530 | 7 | 12.8 | 26 | 1.5 |
| | Example 1 | | | | | | | |
| | Comparative | 179 | 0.284 | 529 | 5.2 | 12.5 | 27.1 | 1.75 |
| | Example 5 | | | | | | | |

| | | | | Properties of white LED | |
|---|---|---|---|---|---|
| | | Powder properties and | | Luminous flux intensity | Variation magnitude of |
| | | physical properties | | retention rate after | chromaticity x, after |
| | | of green phosphor | | exposure at 85° C., | exposure at 85° C., |
| | | | D50/average | relative humidity of | relative humidity of |
| | | Average | particle size | 85%, energization | 85%, energization |
| | | particle size | R (Formula | current of 45 mA, for | current of 45 mA, for |
| | | R (μm) | (1)) | 1000 hours | 1000 hours |
| Phosphor | Example 1 | 9.9 | 1.30 | 90.8% | −0.006 |
| (a) | | | | | |
| — | Comparative | 8.0 | 1.60 | 88.1% | −0.008 |
| | Example 1 | | | | |
| | Comparative | 7.0 | 1.79 | 85.9% | −0.009 |
| | Example 5 | | | | |

TABLE 2

| | | Powder properties and physical properties of green phosphor | | | | | | |
|---|---|---|---|---|---|---|---|---|
| | | Excitation at 455 nm | | | | | | |
| | | Emission | | Peak | Particle size | | | |
| | | intensity | Chromaticity | wavelength | D10 | D50 | D90 | |
| | | (%) | x | (nm) | (μm) | (μm) | (μm) | (D90 − D10)/D50 |
| Phosphor | Example 2 | 235 | 0.330 | 540 | 7.9 | 15.7 | 28.9 | 1.3 |
| (a) | | | | | | | | |
| — | Comparative | 238 | 0.331 | 540 | 8.5 | 16.1 | 29.2 | 1.3 |
| | Example 2 | | | | | | | |
| | Comparative | 231 | 0.329 | 539 | 6.5 | 15.5 | 31.5 | 1.61 |
| | Example 6 | | | | | | | |

| | | | | Properties of white LED | |
|---|---|---|---|---|---|
| | | Powder properties and | | Luminous flux intensity | Variation magnitude of |
| | | physical properties | | retention rate after | chromaticity x, after |
| | | of green phosphor | | exposure at 85° C., | exposure at 85° C., |
| | | | D50/average | relative humidity of | relative humidity of |
| | | Average | particle size | 85%, energization | 85%, energization |
| | | particle size | R (Formula | current of 45 mA, for | current of 45 mA, for |
| | | R (μm) | (1)) | 1000 hours | 1000 hours |
| Phosphor | Example 2 | 13.5 | 1.16 | 90.7% | −0.006 |
| (a) | | | | | |
| — | Comparative | 11.2 | 1.44 | 89.4% | −0.007 |
| | Example 2 | | | | |
| | Comparative | 10.5 | 1.48 | 88.2% | −0.008 |
| | Example 6 | | | | |

TABLE 3

| | | Powder properties and physical properties of green phosphor | | | | | | |
|---|---|---|---|---|---|---|---|---|
| | | Excitation at 455 nm | | | | | | |
| | | Emission | | Peak | Particle size | | | |
| | | intensity | Chromaticity | wavelength | D10 | D50 | D90 | |
| | | (%) | x | (nm) | (μm) | (μm) | (μm) | (D90 − D10)/D50 |
| Phosphor | Example 3 | 282 | 0.368 | 545 | 11.1 | 20.6 | 38.4 | 1.3 |
| (a) | Example 4 | 281 | 0.37 | 545 | 15 | 26.0 | 45 | 1.2 |
| | Example 5 | 280 | 0.369 | 545 | 9.5 | 19.5 | 41.1 | 1.62 |
| — | Comparative | 284 | 0.37 | 545 | 12.2 | 20.3 | 38.8 | 1.3 |
| | Example 3 | | | | | | | |
| | Comparative | 277 | 0.37 | 545 | 10 | 19.8 | 42.3 | 1.63 |
| | Example 4 | | | | | | | |

| | | | | Properties of white LED | |
|---|---|---|---|---|---|
| | | Powder properties and | | Luminous flux intensity | Variation magnitude of |
| | | physical properties | | retention rate after | chromaticity x, after |
| | | of green phosphor | | exposure at 85° C., | exposure at 85° C., |
| | | | D50/average | relative humidity of | relative humidity of |
| | | Average | particle size | 85%, energization | 85%, energization |
| | | particle size | R (Formula | current of 45 mA, for | current of 45 mA, for |
| | | R (μm) | (1)) | 1000 hours | 1000 hours |
| Phosphor | Example 3 | 16.2 | 1.27 | 93.5% | −0.005 |
| (a) | Example 4 | 21.0 | 1.24 | 95.4% | −0.004 |
| | Example 5 | 15.4 | 1.27 | 89.6% | −0.006 |
| — | Comparative | 13.0 | 1.56 | 89.3% | −0.007 |
| | Example 3 | | | | |
| | Comparative | 12.5 | 1.58 | 88.6% | −0.008 |
| | Example 4 | | | | |

<Conversion into White LED>

When the conversion into a white LED was performed by using the above-described green phosphor, the green phosphor (a) and the red phosphor (b) K₂SiF₆:Mn were mixed with each other in such a way that when combined with a blue LED a chromaticity x of 0.272 and a chromaticity y of 0.278 were obtained, and thus a phosphor mixture was obtained; by using such phosphor mixtures according to Examples and Comparative Examples white LEDs were prepared and the properties thereof were measured. The results thus obtained are shown in Tables 1 to 3.

It is to be noted that the red phosphor (b) was prepared under the following conditions.

The production method of the red phosphor (b) is a production method of a phosphor represented by the general formula: A₂MF₆:Mn, has a melting step of melting the raw materials, and a reprecipitation step of precipitating the phosphor from the raw materials, wherein the element A is K (potassium), the element M is Si (silicon), F is fluorine, and Mn is manganese.

<Raw Materials in Addition Step>

The raw materials of the phosphor in the addition step of the red phosphor (b) were specifically set to be a K₂SiF₆ powder (Special Grade, Kanto Chemical Co., Inc.), and K₂MnF₆ (produced by the below-described production method). Either of these raw materials were powdery. As the fluorohydric acid for dissolving these raw materials, a fluorohydric acid solution having a concentration of 55% by mass was adopted.

<Step of Producing K₂MnF₆>

The production of K₂MnF₆ included the following production step.

In a 1-liter volume beaker made of Teflon (registered trademark), 800 ml of a fluorohydric acid having a concentration of 40% by mass was placed, 260 g of a KHF₂ powder (Special grade reagent, manufactured by Wako Pure Chemical Industries, Ltd.) and 12 g of a potassium permanganate (First grade reagent, manufactured by Wako Pure Chemical Industries, Ltd.) were dissolved. While the fluorohydric acid reaction solution was being stirred with a magnetic stirrer, 8 ml of a 30% hydrogen peroxide solution (special grade reagent) was dropwise added little by little to the fluorohydric acid reaction solution. When the dropwise added amount of the hydrogen peroxide solution exceeded a certain amount, yellow particles began to precipitate, and the color of the reaction solution began to change from purple. After the hydrogen peroxide solution was dropwise added in a certain amount, the reaction solution was continuously stirred for a while, then the stirring was ceased, and the precipitated particles were deposited. After the precipitation, the supernatant liquid was removed, methanol was added to the reaction solution, the reaction solution was stirred and allowed to stand still, the supernatant liquid was removed, and further, methanol was added; such a set of operations was repeated until the reaction solution became neutral. Subsequently, the precipitated particles were collected by filtration, and further dried, methanol was completely removed by evaporation, and thus 19 g of a K₂MnF₆ powder was obtained. All these operations were performed at normal temperature.

<Dissolution Step>

The dissolution step of the red phosphor (b) is described.

At normal temperature, in a 500-ml volume beaker made of Teflon (registered trademark), 100 ml of a fluorohydric acid having a concentration of 55% by mass was placed, and 3 g of a K₂SiF₆ powder (Special Grade, Kanto Chemical Co., Inc.) and 0.5 g of K₂MnF₆ were sequentially dissolved in the fluorohydric acid. The addition amounts of these raw materials are the addition amounts equal to or less than the saturation solubility of the phosphor represented by the general formula A₂MF₆:Mn.

<Reprecipitation Step>

To the resulting solution, 150 ml of water was dropwise added from two positions, then the solution was stirred with a magnetic stirrer for 10 minutes, and then the solution was allowed to stand still. By allowing the solution to stand still, the precipitated phosphor was deposited in the bottom part of the container.

The amount of water was set to be 150 ml, for the purpose of allowing the fluorohydric acid concentration in the fluorohydric acid solution to be 22% by mass when water was added in the reprecipitation step.

<Cleaning Step>

After the presence of the phosphor was identified, the supernatant liquid was removed, a cleaning with a 20% by mass fluorohydric acid and methanol, the solid content was separated and collected by filtration, and the remaining methanol was evaporated and removed by a drying treatment.

<Classification Step>

A nylon sieve having an opening of 75 μm was used on the phosphor after the drying treatment, only the fraction passing through the sieve was classified, and finally 1.3 g of a yellow phosphor K₂SiF₆:Mn phosphor was obtained.

<Optical Properties of Red Phosphor (b)>

The optical properties of the phosphor obtained by the production method of the red phosphor (b) are described. The excitation wavelength of the fluorescence spectrum and the monitor fluorescence wavelength of the excitation spectrum measured with the fluorescence spectrophotometer (F-7000, manufactured by Hitachi High-Technologies Corp.) were 455 nm and 632 nm, respectively. The phosphor was a phosphor having two excitation bands, namely, an ultraviolet band in the vicinity of a peak wavelength of 350 nm and a blue band in the vicinity of a peak wavelength of 450 nm, and a plurality of narrow band emissions in the red region of 600 to 700 nm. The external quantum efficiency, absorptance and internal quantum efficiency of the red phosphor (b) were 82%, 74%, and 61%, respectively. The chromaticity coordinates (x, y) of the red phosphor were (0.694, 0.306).

When the green phosphor (a) and the red phosphor (b) were mixed with each other, the green phosphor (a) and the red phosphor (b) were weighed out in a total amount of 2.5 g, and were mixed in a vinyl bag, and the phosphor mixture was mixed with 47.5 g of a silicone resin (OE6656, Dow Corning Toray Co., Ltd.), with a rotation-revolution type mixer (Awatori Rentaro (registered trademark) ARE-310, manufactured Thinky Corp.).

The mounting of an LED was performed as follows: the LED was placed on the bottom part of a concave package body, and wire-bonded to an electrode on the substrate; then, the phosphor mixed with a silicone resin was injected from a microsyringe. After the mounting, curing was performed at 120° C., then post curing was applied at 110° C. for 10 hours, and then sealing was performed. An LED having an emission peak wavelength of 448 nm, and a chip size of 1.0 mm×0.5 mm was used.

The long-term reliability test used the phosphors listed in Table 1, Table 2 and Table 3; while the prepared white LEDs (white LEDs prepared when the luminous flux was evaluated) were being energized at 45 mA, a high-temperature, high-humidity, long-time exposure was performed at 85° C., at a relative humidity of 85%, and for 1000 hours; then, after the temperature was decreased to 25° C., (1) the luminous flux, and (2) the chromaticity x were measured; the luminous flux before the exposure at 25° C. was taken as 100%, and (1) the luminous flux intensity retention rate and (2) the variation magnitude of the chromaticity x after the exposure were measured.

When Example 1, Comparative Example 1, and Comparative Example 5, which are nearly the same as each other with respect to the chromaticity x, the peak wavelength, the emission intensity, and the D50 of the green phosphor, are compared with each other, Example 1 has a D50/average particle size R value smaller than 1.4, a higher average particle size R, and conceivably a smaller specific surface area. As compared with Comparative Example 1 and Comparative Example 5, Example 1 has a higher luminous flux intensity retention rate, and a smaller variation magnitude of the chromaticity x, after the exposure at 85° C., at a relative humidity of 85%, at an energization current of 45 mA, for 1000 hours.

When Example 2, Comparative Example 2, and Comparative Example 6, which are nearly the same as each other with respect to the chromaticity x, the peak wavelength, the emission intensity, and the D50 of the green phosphor, are compared with each other, Example 2 has a D5 average particle size R value smaller than 1.4, a higher average particle size R, and conceivably a smaller specific surface area. As compared with Comparative Example 2 and Comparative Example 6, Example 2 has a higher luminous flux intensity retention rate, and a smaller variation magnitude of the chromaticity x, after the exposure at 85° C., at a relative humidity of 85%, at an energization current of 45 mA, for 1000 hours.

When Example 3, Example 4, Example 5, Comparative Example 3, and Comparative Example 4, which are nearly the same as each other with respect to the chromaticity x, the peak wavelength, the emission intensity, and the D50 of the green phosphor, are compared with each other, Example 3, Example 4, and Example 5 each have a D50/average particle size R value smaller than 1.4, a higher average particle size R, and conceivably a smaller specific surface area. As compared with Comparative Example 3 and Comparative Example 4, Example 3, Example 4, and Example 5 each have a higher luminous flux intensity retention rate, and a smaller variation magnitude of the chromaticity x, after the exposure at 85° C., at a relative humidity of 85%, at an energization current of 45 mA, for 1000 hours. In addition, Example 3 and Example 4 each have a (D90−D10)/D50 value of smaller than 1.6, and Example 5 has a (D90−D10)/D50 value of more than 1.6, and consequently Example 3 and Example 4 each have a higher luminous flux intensity retention rate, and a smaller variation magnitude of the chromaticity x, after the exposure at 85° C., at a relative humidity of 85%, at an energization current of 45 mA, for 1000 hours.

### INDUSTRIAL APPLICABILITY

The phosphor of the present invention may be used in a white light emitting device, and such a white light emitting device may be used in the applications to back light of liquid crystal panel, illuminating device, signal device, image display device, and projector.

1. A β-type SiAlON phosphor (a), wherein the volume median particle size D50 [μm] and the average particle size R [μm] calculated from the surface area determined by the air permeability method satisfy the following formula (1):
D50/R<1.4 Formula (1)

2. The phosphor (a) according to claim 1, wherein when the volume of the whole of the particles is defined as 100%, and when D10 [μm] represents a particle size at which the volume integrated from the smallest particle size is 10% in terms of the integrated volume percentage, and D90 [μm] represents a particle size at which the volume integrated from the smallest particle size is 90% in terms of the integrated volume percentage, the phosphor (a) satisfies the following formula (2):
1.6>(D90−D10)/D50 Formula (2)

3. A light emitting device using the phosphor (a) according to claim 1.

4. The light emitting device according to claim 3, being a white light emitting device.

5. The light emitting device according to claim 3, comprising the phosphor (a), and at least a red phosphor, as the other phosphor, made of a fluoride or a nitride.

6. The light emitting device according to claim 5, wherein the fluoride red phosphor is K₂SiF₆:Mn, and the nitride red phosphor is selected from one or more of CaAlSiN₃:Eu, (Sr,Ca)AlSiN₃:Eu, and Sr₂Si₅N₅:Eu.
